(19) United States
(12) Patent Application Publication
(10) Pub. No.: US 2004/0091630 A1
(43) Pub. Date: May 13, 2004

(54) Deposition of a solid by thermal decomposition of a gaseous substance in a cup reactor

(75) Inventor: Raymund Sonnenschein, Frankfurt (DE)

Correspondence Address: OBLON, SPIVAK, MCCLELLAND, MAIER & NEUSTADT, P.C., 1940 DUKE STREET, ALEXANDRIA, VA, 22314, US

(73) Assignee: DEGUSA AG, Duesseldorf (DE)

(21) Appl. No.: 10/663,789

(22) Filed: Sep. 17, 2003

(30) Foreign Application Priority Data
Sep. 17, 2002 (DE) 102 43 022.5

(51) Int. Cl. C23C 16/00

(52) U.S. Cl. 427/428.1; 137/470

(57) ABSTRACT

A process for depositing a solid (B) proceeds by targeted thermal decomposition of a gaseous substance (A). The substance (A) has a higher density than the gaseous product (C) formed during the decomposition. In the process, a device is used which has a cup (1), the base (1.1) of which is oriented in the direction of the force of gravity (g) and the opening region (1.2) of which is oriented in the opposite direction to the force of gravity (g). The cup (1) can be heated directly or indirectly by a heating, temperature-measuring and control unit (3.3). The device further contains a substance-adding unit (2) with substance feedline (3.1) and metering unit (3.2), the substance-adding unit (2) being oriented with the substance outlet (2.1) in the direction of the force of gravity (g) and projecting into the free volume of the cup (1) between the base (1.1) and opening region (1.2). The device also has a reactor casing (3) and an outlet (3.6) for gaseous product (C). The process and device are used, for example, to produce bodies of high-purity polycrystalline silicon in ingot form by controlled thermal decomposition of monosilane.

### BACKGROUND OF THE INVENTION

1. Field of the Invention

The present invention relates to a process and a device for depositing a solid (B) by thermal decomposition of a gaseous substance (A) in a reactor. The gaseous substance (A) has a higher density than the gaseous products (C) formed during the decomposition.

2. Discussion of the Background

Decomposing silanes at elevated temperatures has been known. It results in silicon and byproducts. In this way polycrystalline silicon may be deposited. This method is also known as the CVD (chemical vapor deposition) process. Previous processes which have been used on an industrial scale for production of pure polycrystalline silicon use trichlorosilane (HSiCl₃) or monosilane (SiH₄) as the raw material.

If trichlorosilane is used, the byproducts formed are silicon tetrachloride, chlorine, hydrogen and other, generally recyclable substances.

By contrast, if monosilane is used, the only byproduct produced is hydrogen. By way of example, monosilane can be decomposed at a silicon rod which has been heated by means of electric current (Siemens process) or in a heated fluidized layer.

In more recent processes, there has been a trend toward deposition in a horizontally or vertically oriented tube (U.S. Pat. No. 6,284,312, U.S. Pat. No. 6,365,225, WO 01/61070).

The high-purity silicon which has been obtained using CVD processes is generally used in melting processes for the production of monocrystalline or polycrystalline silicon. Particularly in the case of the melting process, it is endeavored to use the high-purity silicon as far as possible in lump form, as granules, as an ingot or as a rod.

Unfortunately, in the known CVD processes a high proportion of silicon in dust form is produced, which contributes to a considerable loss of material if the target product is silicon in lump form.

Furthermore, the known processes lead to undesirable caking of silicon to a greater or lesser extent on the walls of the reaction vessels.

Furthermore, it is generally only possible to use highly diluted substrate gas.

In addition, a high energy consumption resulting from high quantitative flows, due to high dilution when using monosilane or due to numerous byproducts when using trichlorosilane, is disadvantageous.

In the known processes, in which through-flow reactors are used, the off-gas also contains, in addition to dust, significant quantities of starting material, which requires off-gas cleaning, which is generally complex, or complex recycling.

### SUMMARY OF THE INVENTION

It is an object of the present invention to provide a process and a device that reduces the abovementioned drawbacks as far as possible. This and other objects have been achieved by the present invention the first embodiment of which includes a device, comprising:

a cup, a base of which is oriented in the direction of the force of gravity, and an opening region of which is oriented in the opposite direction to the force of gravity, and wherein said cup is heatable directly or indirectly by a heating, temperature-measuring control unit;

a substance-adding unit having a substance feedline and a metering unit, the substance-adding unit being oriented with a substance outlet in the direction of the force of gravity and projecting into a free volume of said cup between said base and said opening region;

a reactor casing; and

an outlet for a gaseous product.

Another embodiment of the present invention includes a process for depositing a solid (B), comprising:

heating the base, the wall or both of said cup of the above device;

introducing a gaseous substance (A) an interior of said cup via said substance-adding unit;

thermally decomposing a gaseous substance (A), thereby forming said solid (B) and at least one gaseous product (C) and depositing said solid (B) substantially on an inner side of said cup; and

removing said gaseous product (C) from said device system through said outlet;

wherein said substance (A) has a higher density than said gaseous product (C).

### BRIEF DESCRIPTION OF DRAWINGS

FIGS. 1, 2 and 3 show sketches of preferred embodiments of devices according to the present invention.

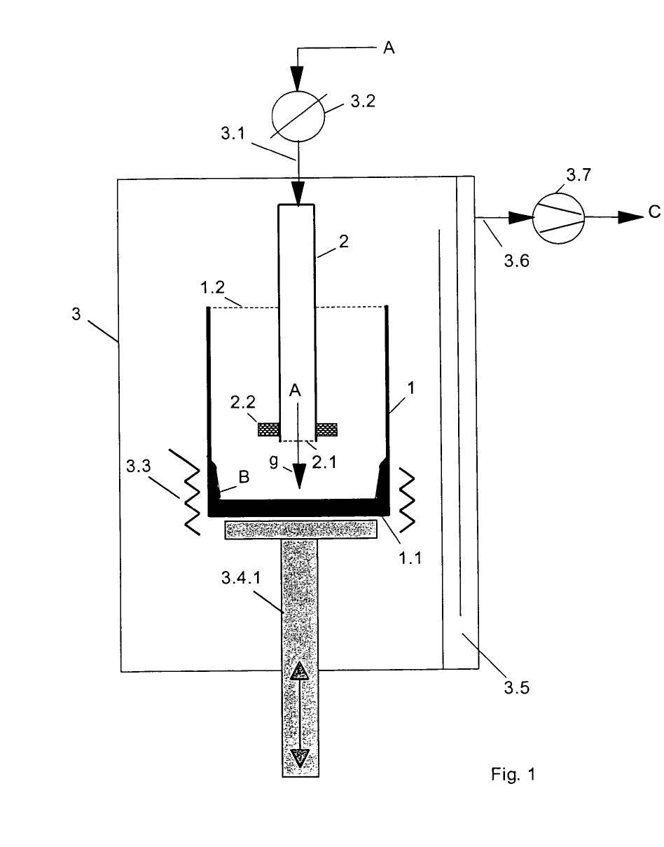

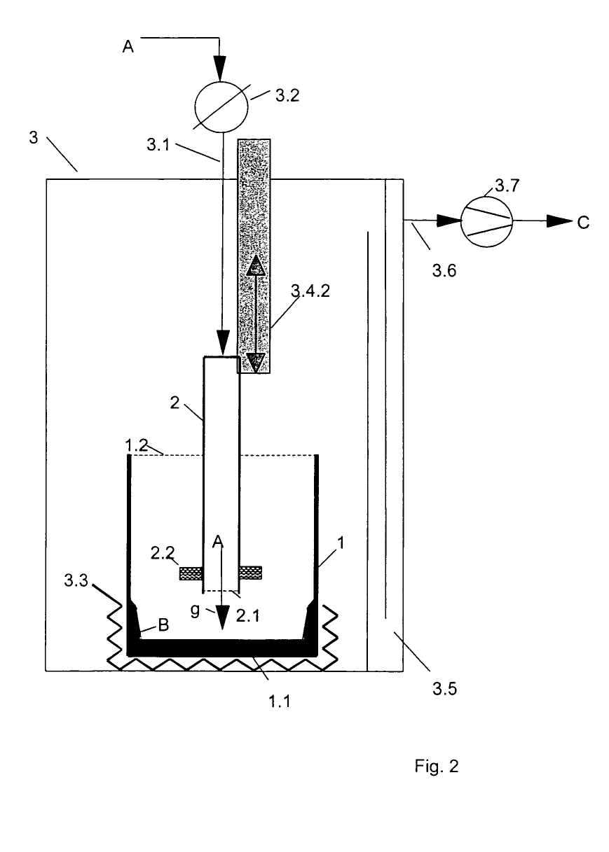

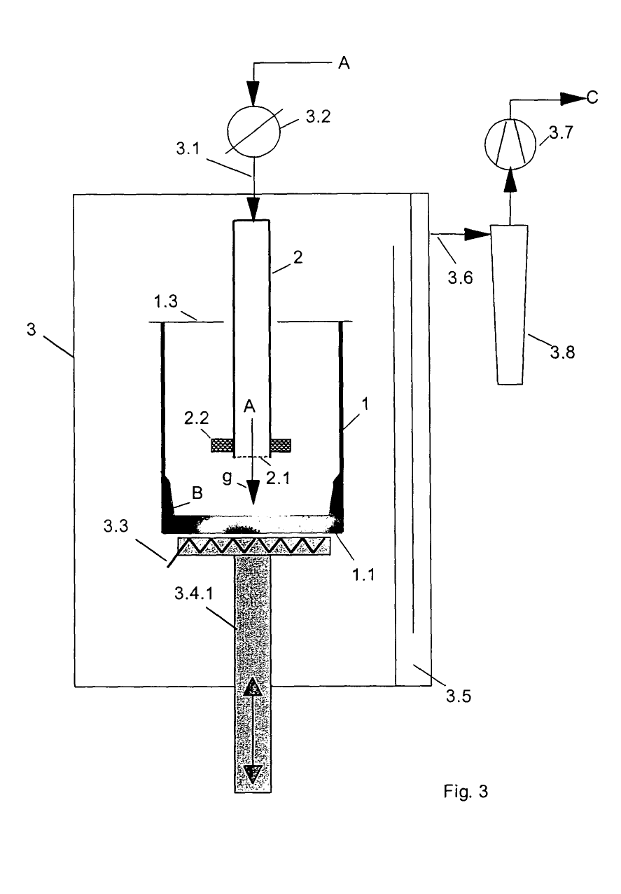

### DETAILED DESCRIPTION OF THE INVENTION

Surprisingly, it has been found that a solid (B) can be produced in lump form with a relatively low production of silicon dust in a simple and particularly economic way by controlled thermal decomposition of a gaseous substance (A) if the decomposition and deposition of the substance (A) is carried out in a specific device. This device has a cup (1), the base (1.1) of which is oriented in the direction of the force of gravity (g) and the opening region (1.2) of which is oriented in the opposite direction to the force of gravity (g). The cup (1) can be heated directly or indirectly by a heating, temperature-measuring and control unit (3.3). The device further includes a substance-adding unit (2) with substance feedline (3.1) and metering unit (3.2). The substance-adding unit (2) is oriented with the substance outlet (2.1) in the direction of the force of gravity (g) and projects into the free volume of the cup (1) between the base (1.1) and opening region (1.2). The device additionally includes a reactor casing (3), which can be opened in a suitable way and substantially closes off the units (1) and (2) from gas exchange with the environment. In addition, the device has an outlet (3.6) for predominantly gaseous products (C).

Monosilane can be thermally decomposed as substance (A) and polycrystalline silicon can be deposited as solid (B) in the cup (1). Substance (A) may be a single gas or a mixture of gases, and has a higher density than the gaseous products (C) formed during the decomposition. Preferably, (A) may include a single silane or a mixture of silanes.

The present invention is particularly economical, since the outlay on equipment is relatively low, and when monosilane is used as substance (A) the only off-gas formed is hydrogen, possibly with small amounts of monosilane. In addition, a relatively low level of silicon dust is formed in the process. Due to the procedure and device according to the present invention, there is generally no caking of solid (B) on the reactor wall (3). Furthermore, practically the only off-gas obtained is free hydrogen. The deposition rate of solid (B) is generally >97%. Furthermore, the dust content in the off-gas (C) after outlet (3.6) is generally very low. Also, the present process is particularly advantageous in energy terms, since, inter alia, relatively low substance flow rates can be used.

Therefore, the process according to the present invention carried out in a device according to the present invention advantageously produces high-purity silicon in ingot form, which can be used, for example, in melting processes to obtain a monocrystalline or polycrystalline silicon.

Preferably, the cup (1) and/or the substance-adding unit (2) can be raised and lowered in the direction of the force of gravity by at least one lifting device (3.4.1 and 3.4.2, respectively). The lifting device 3.4.1 may preferably be heatable, so that, for example, the stand plate of the cup (1) includes a heating unit (3.3).

Furthermore, in the cup reactor according to the present invention, a turbulence barrier (3.5) for gas calming and particle deposition may be connected upstream of the outlet (3.6).

To set and control the quantitative throughput of (A) in the present device, a gas-conveying unit (3.7) may be connected downstream of the outlet (3.6).

Furthermore, in the device according to the present invention, a dust separation means (3.8), for example a dust filter, may be connected upstream and/or downstream of the gas-conveying unit (3.7).

The substance-adding unit (2) of the present cup reactor is preferably equipped with a temperature detector (2.2) in the region of the substance outlet (2.1).

The substance-adding unit (2) may preferably consist of the solid (B), quartz glass or a metallic material, such as stainless steel, titanium or a nickel-based alloy. Furthermore, the stainless steel used may be a high-temperature-resistant nickel alloy, for example Inconell®, or also Ti, Nb, Ta. Preferably, the lance of the unit (2) is coolable. The tip of the lance is preferably in the shape of an inverted funnel, so that the slowest possible addition of the gas (A) to the cup (1) can be ensured, and to prevent turbulence in the stratified gas as far as possible.

The cup (1) of the reactor according to the present invention preferably consists of the solid (B) and appropriately has a side height of 10 to 200 cm and a base area, i.e. standing surface area, of preferably from 10 to 10,000 cm². The side height of cup (1) includes all values and subvalues therebetween, especially including 20, 30, 40, 50, 60, 70, 80, 90, 100, 110, 120, 130, 140, 150, 160, 180 and 190 cm. The base area includes all values and subvalues therebetween, especially including 100, 500, 1000, 1500, 2000, 2500, 3000, 3500, 4000, 4500, 5000, 5500, 6000, 6500, 7000, 7500, 8000, 8500, 9000 and 9500 cm². The unit (1) and the lance of the unit (2) appropriately consist of a high-purity silicon.

Preferably, the cup (1) of the device according to the present invention may comprise a disk with a thickness of from 0.01 to 1 cm, preferably 0.3 to 2 mm. The disk can be made from high-purity silicon, as base (1.1), and a silicon tube as the wall, with a wall thickness of from 0.01 to 1 cm, preferably 0.3 to 2 mm, and preferably a diameter of from 10 to 50 cm. The tube preferably stands substantially vertically, by means of one of the two opposite opening surfaces of the tube, on the planar surface of the silicon disk. The external diameter of the tube is preferably less than or equal to the diameter of the silicon disk. In this case, it is preferable for the silicon disk used to be a wafer. The axis of a tube of this type is oriented substantially perpendicularly to at least one of the two opening surfaces of the tube. It is appropriate for at least one opening surface to be planar, oriented perpendicular to the tube axis and to serve as a contact surface with respect to the planar surface of the wafer. However, the edges of the opening surface of the tube may also be of toothed shape or of any other irregular design. The thickness of the disk includes all values and subvalues therebetween, especially including 0.05, 0.1, 0.2, 0.3, 0.4, 0.5, 0.6, 0.7, 0.8 and 0.9 cm. The wall thickness of the silicon tube includes all values and subvalues therebetween, especially including 0.05, 0.1, 0.2, 0.3, 0.4, 0.5, 0.6, 0.7, 0.8, 0.9 cm. The diameter of the silicon tube includes all values and subvalues therebetween, especially including 15, 20, 25, 30, 35, 40 and 45 cm.

In the device according to the present invention, the cup (1), at the level of the opening region (1.2), may additionally be covered with a plate (1.3) which, in the center, has a passage for the unit (2), so that the gas permeability is generally ensured. A plate of this type with a hole as a passage for the unit (2) may, for example, consist of the solid (B).

The device according to the present invention is preferably also equipped with at least one flap which closes in a gastight manner or a cover which closes in a gastight manner as part of the reactor casing (3).

Furthermore, the reactor casing (3) may be equipped with a cooling means and, if appropriate, a heating means. The reactor casing (3) is expediently designed for a temperature of from −100 to +400° C., preferably 10 to 100° C. The temperature includes all values and subvalues therebetween, especially including −50, 0, 50, 100, 150, 200, 250, 300 and 350° C. The reactor casing (3) should also be of pressure-resistant design, with an operating pressure in the cup reactor of from 0.1 mbar absolute to 50 bar absolute, in particular 0.1 to 5 bar absolute, being preferred. The operating pressure includes all values and subvalues therebetween, especially including 0.5, 1, 5, 10, 100, 500 mbar absolute, 1, 5, 10, 15, 20, 25, 30, 35, 40 and 45 bar absolute. Furthermore, a gastight design is preferred, in particular with respect to atmospheric oxygen.

The present invention is also includes a process for depositing a solid (B) by thermal decomposition of a gaseous substance (A), the substance (A) used having a higher density than the gaseous products (C) formed during the decomposition, in a device according to the present invention, in which

the base and/or the side wall of the cup (1) is/are heated,

the gaseous substance (A) is introduced into the interior of cup (1) via the substance-adding unit (2),

the solid (B) which forms as a result of the thermal decomposition (A) is deposited substantially on the inner side of the cup (1), and

the products (C) are removed from the system via the gas phase.

When carrying out the process according to the present invention it is preferable for said device to be evacuated and/or deliberately filled with a gas or gas mixture which has a lower density than the gaseous substance (A), before the gaseous substance (A) is added. In particular, water and oxygen free gases are used. The gases used in this context are preferably hydrogen, nitrogen, ammonia, off-gas (C) as recycled gas, helium, argon or a mixture of the above-mentioned gases.

The substance (A) used in the present process is preferably pure monosilane (SiH₄). It is preferable to use a monosilane with a purity of >99.99%.

However, it is also possible to use other SiH compounds, for example disilanes or suitable mixtures of said SiH compounds. Furthermore, it is possible to use chlorosilanes or mixtures of chlorosilanes and silanes, i.e. SiH compounds. If appropriate, it is also possible for metal hydrogen compounds, such as BH₃, GaH₃, GeH₄, PH₃, AsH₃—to mention but a few examples—to be added in ppm quantities to the gas (A) in order to effect controlled doping of the product. It is preferable to use a gas mixture which contains 0.1 to 100% by volume of substance (A), particularly preferably from 10 to 100% by volume. The amount of substance (A) in the gas mixture includes all values and subvalues therebetween, especially including 5, 10, 15, 20, 25, 30, 35, 40, 45, 50, 55, 60, 65, 70, 75, 80, 85, 90 and 95% by volume.

In particular, in the process according to the present invention the substance (A) used is pure silane (SiH₄) or a mixture thereof with hydrogen, nitrogen, gaseous ammonia, argon and/or helium.

The device according to the present invention for the present process can, however, also be used to carry out reactions other than the decomposition of silanes for deposition of silicon. For example, a mixture of SiH₄ and NH₃ as substance (A) in a cup (1), which consists, for example, of quartz, can be used to deposit silicon nitride.

When carrying out the process according to the present invention, a temperature which is higher than the decomposition temperature of the substance (A) used is expediently used to heat the cup (1), the cup (1) preferably being heated in the region of the base (1.1) and/or lower wall region. The reactor casing (3) can be cooled, in order to avoid undesirable caking on the reactor wall.

The process according to the present invention can be carried out at reduced pressure, at elevated pressure or at standard pressure and at a temperature of from ≧400 to 1200° C. The cup (1) or parts of it are expediently heated to a temperature of from 400 to 1200° C., preferably 600 to 1000° C. The temperature includes all values and subvalues therebetween, especially including 450, 500, 550, 600, 650, 700, 750, 800, 850, 900, 950, 1000, 1050, 1100, and 1150° C.

In the present process, the substance (A) or a corresponding gas mixture is expediently added via the units (3.2), (3.1) and (2), and this addition can be assisted by the unit (3.8).

In this case, it is preferable for the substance outlet (2.1) to project into the free volume of the cup (1) between base (1.1) and opening region (1.2), the orientation of substance outlet (2.1) with respect to the base (1.1) of the cup (1) being suitably controlled and tracked by means of a temperature detector (2.2).

Furthermore, the pressure in the reactor and the feed of substance (A) are preferably controlled by means of the discharge of the gaseous products (C) by means of gas-conveying unit (3.7) and/or by the metering unit (3.2).

In general, the process according to the present invention can be carried out as follows:

As a rule, the cup reactor is first of all dried, for example by being heated, and is then evacuated and filled with a gas which is free of O₂ and H₂O and which has a lower density than the substance (A) which is to be decomposed. It is now possible for the cup (1) to be brought to its operating temperature. The substance (A) or a suitably diluted gas mixture is then admitted to the interior of the cup (1) via the units (3.2), (3.1) and (2). The progress of the deposition of solid (B) can be determined, for example, by changing the temperature at the unit (2.2) and adjusting the unit (2). Furthermore, the quantity of (A) added can be controlled by means of the units (3.2) and/or (3.8).

Therefore, the process according to the present invention can be used for advantageous production of high-purity silicon in above described device which has been developed for this purpose.

German patent application 102 43 022.5, filed Sep. 17, 2002, is incorporated herein by reference.

Numerous modifications and variations on the present invention are possible in light of the above teachings. It is therefore to be understood that within the scope of the appended claims, the invention may be practiced otherwise than as specifically described herein.

1. A device, comprising:
a cup, a base of which is oriented in the direction of the force of gravity, and an opening region of which is oriented in the opposite direction to the force of gravity, and wherein said cup is heatable directly or indirectly by a heating, temperature-measuring control unit;
a substance-adding unit having a substance feedline and a metering unit, the substance-adding unit being oriented with a substance outlet in the direction of the force of gravity and projecting into a free volume of said cup between said base and said opening region;
a reactor casing; and
an outlet for a gaseous product.

2. The device as claimed in claim 1, wherein said cup, said substance-adding unit or both can be raised and lowered in the direction of the force of gravity by at least one lifting device.

3. The device as claimed in claim 1, wherein a turbulence barrier is connected upstream of said outlet.

4. The device as claimed in claim 1, wherein a gas-conveying unit is connected downstream of said outlet.

5. The device as claimed in claim 4, wherein a dust separator is connected upstream, downstream or both of said gas-conveying unit.

6. The device as claimed in claim 1, wherein said substance-adding unit is equipped with a temperature detector in the region of said substance outlet.

7. The device as claimed in claim 1, wherein said substance-adding unit comprises a solid to be thermally decomposed, quartz glass or a metallic material.

8. The device as claimed in claim 1, wherein said cup comprises a solid to be thermally decomposed, has a side height of 10 to 200 cm and a base area of from 10 to 10,000 cm².

9. The device as claimed in claim 1, wherein said cup and a lance of said substance-adding unit comprise high-purity silicon.

10. The device as claimed in claim 1, wherein said cup comprises
a silicon disk as said base, and
a silicon tube as a wall of said cup;
wherein said silicon tube has two opening surfaces;
wherein said silicon tube stands substantially vertically based on one of said two opposite opening surfaces of said silicon tube, on a planar surface of said silicon disk; and
wherein an external diameter of said silicon tube is less than or equal to a diameter of said silicon disk.

11. The device as claimed in claim 10, wherein said silicon disk is a wafer.

12. The device as claimed in claim 1, wherein said cup, at the level of said opening region, is covered with a plate which, in the center, has a passage for sais substance-adding unit.

13. The device as claimed in claim 1, which is equipped with at least one flap which closes in a gastight manner or a cover which closes in a gastight manner as part of said reactor casing.

14. The device as claimed in claim 1, wherein said reactor casing is equipped with a cooler and, optionally, a heater.

15. The device as claimed in claim 1, wherein said reactor casing is pressure-resistant and vacuum-resistant.

16. The device as claimed in claim 1, which is gastight.

17. A process for depositing a solid (B), comprising:
heating the base, the wall or both of said cup of the device according to claim 1;
introducing a gaseous substance (A) an interior of said cup via said substance-adding unit;
thermally decomposing a gaseous substance (A), thereby forming said solid (B) and at least one gaseous product (C) and depositing said solid (B) substantially on an inner side of said cup; and
removing said gaseous product (C) from said device system through said outlet;
wherein said substance (A) has a higher density than said gaseous product (C).

18. The process as claimed in claim 17, wherein said device is evacuated and/or deliberately filled with a gas or gas mixture, each of which have a lower density than said gaseous substance (A), before the gaseous substance (A) is added.

19. The process as claimed in claim 17, wherein said substance (A) is monosilane (SiH₄).

20. The process as claimed in claim 17, wherein said substance (A) is silane (SiH₄) mixed with a member selected from the group consisting of hydrogen, nitrogen, gaseous ammonia, argon, helium and mixtures thereof.

21. The process as claimed in claim 17, wherein the heating of said cup (1) establishes a temperature which is higher than a decomposition temperature of monosilane.

22. The process as claimed in claim 17, which is carried out at reduced pressure, at elevated pressure or at standard pressure and at a temperature of ≧400 up to 1200° C.

23. The process as claimed in claim 17, wherein said reactor casing is cooled.

24. The process as claimed in claim 17, wherein said substance outlet projects into the free volume of said cup between said base and said opening region, and the orientation of said substance outlet with respect to said base of said cup is controlled and tracked by a temperature detector.

25. The process as claimed in claim 17, wherein a pressure in said device and in a feed of said substance (A) are controlled by the discharge of said gaseous product (C) through said gas-conveying unit and/or by said metering unit.

26. The process as claimed in claim 17, wherein a substantially homogeneous body in ingot form comprising said solid (B) is produced by thermally decomposing said substance (A) in said cup.

27. The device as claimed in claim 2, wherein a turbulence barrier is connected upstream of said outlet.
